(19) United States
(12) Patent Application Publication
(10) Pub. No.: US 2018/0321327 A1
(43) Pub. Date: Nov. 8, 2018

(54) Battery Testing Assembly

(71) Applicant: Dan Alberti, Mount Prospect, IL (US)

(72) Inventor: Dan Alberti, Mount Prospect, IL (US)

(21) Appl. No.: 15/584,082

(22) Filed: May 2, 2017

(51) Int. Cl. G01R 31/36; H01M 10/42; H01M 6/50

(52) U.S. Cl. CPC G01R 31/3696; G01R 31/3627; H01M 6/5083; H01M 10/4285

(57) ABSTRACT

A battery testing assembly for testing a charge of a battery includes a belt that is selectively positioned between a positive terminal and a negative terminal of a battery. The belt is comprised of an electrically conductive material to complete a circuit between the positive and negative terminals. A contact is coupled to the belt to be placed in electrical communication with the negative terminal of the battery. A light emitter is coupled to the belt to be placed in electrical communication with the positive terminal of the battery. The light emitter emits light when the belt is positioned between the negative and positive terminals thereby facilitating a charge of the battery to be checked.

### CROSS-REFERENCE TO RELATED APPLICATIONS

Not Applicable

### STATEMENT REGARDING FEDERALLY SPONSORED RESEARCH OR DEVELOPMENT

Not Applicable

### THE NAMES OF THE PARTIES TO A JOINT RESEARCH AGREEMENT

Not Applicable

### INCORPORATION-BY-REFERENCE OF MATERIAL SUBMITTED ON A COMPACT DISC OR AS A TEXT FILE VIA THE OFFICE ELECTRONIC FILING SYSTEM.

Not Applicable

### STATEMENT REGARDING PRIOR DISCLOSURES BY THE INVENTOR OR JOINT INVENTOR

Not Applicable

### BACKGROUND OF THE INVENTION

### (1) Field of the Invention

### (2) Description of Related Art including information disclosed under 37 CFR 1.97 and 1.98

The disclosure and prior art relates to testing devices and more particularly pertains to a new testing device for testing a charge of a battery.

### BRIEF SUMMARY OF THE INVENTION

An embodiment of the disclosure meets the needs presented above by generally comprising a belt that is selectively positioned between a positive terminal and a negative terminal of a battery. The belt is comprised of an electrically conductive material to complete a circuit between the positive and negative terminals. A contact is coupled to the belt to be placed in electrical communication with the negative terminal of the battery. A light emitter is coupled to the belt to be placed in electrical communication with the positive terminal of the battery. The light emitter emits light when the belt is positioned between the negative and positive terminals thereby facilitating a charge of the battery to be checked.

There has thus been outlined, rather broadly, the more important features of the disclosure in order that the detailed description thereof that follows may be better understood, and in order that the present contribution to the art may be better appreciated. There are additional features of the disclosure that will be described hereinafter and which will form the subject matter of the claims appended hereto.

The objects of the disclosure, along with the various features of novelty which characterize the disclosure, are pointed out with particularity in the claims annexed to and forming a part of this disclosure.

### BRIEF DESCRIPTION OF SEVERAL VIEWS OF THE DRAWING(S)

The disclosure will be better understood and objects other than those set forth above will become apparent when consideration is given to the following detailed description thereof. Such description makes reference to the annexed drawings wherein:

FIG. 1 is a perspective view of a battery testing assembly according to an embodiment of the disclosure.

FIG. 2 is a back view of an embodiment of the disclosure.

FIG. 3 is a right side view of an embodiment of the disclosure.

FIG. 4 is a top view of an embodiment of the disclosure.

FIG. 5 is a perspective in-use view of an embodiment of the disclosure.

### DETAILED DESCRIPTION OF THE INVENTION

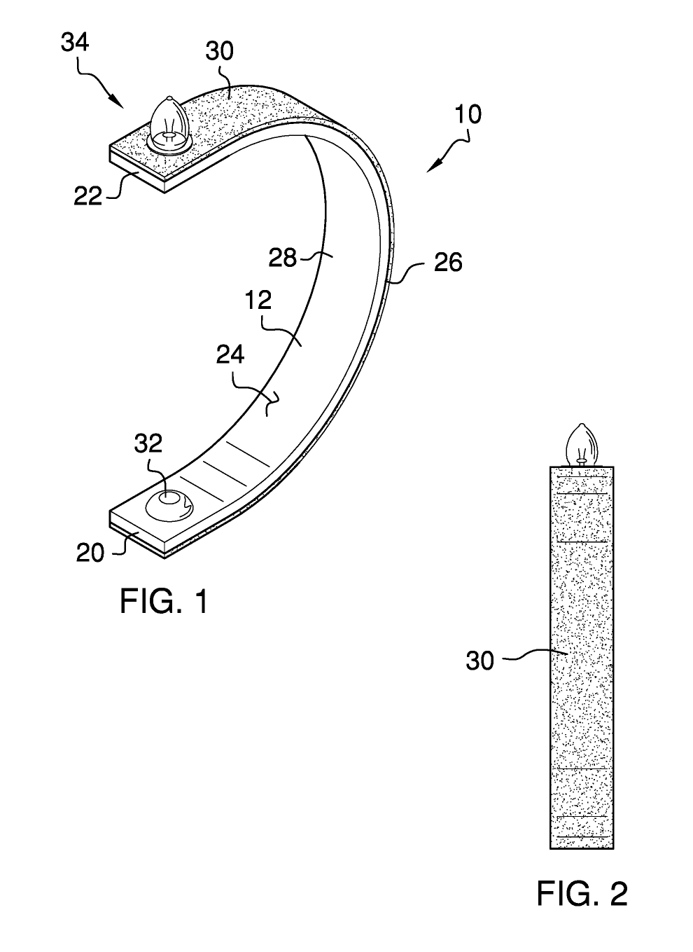

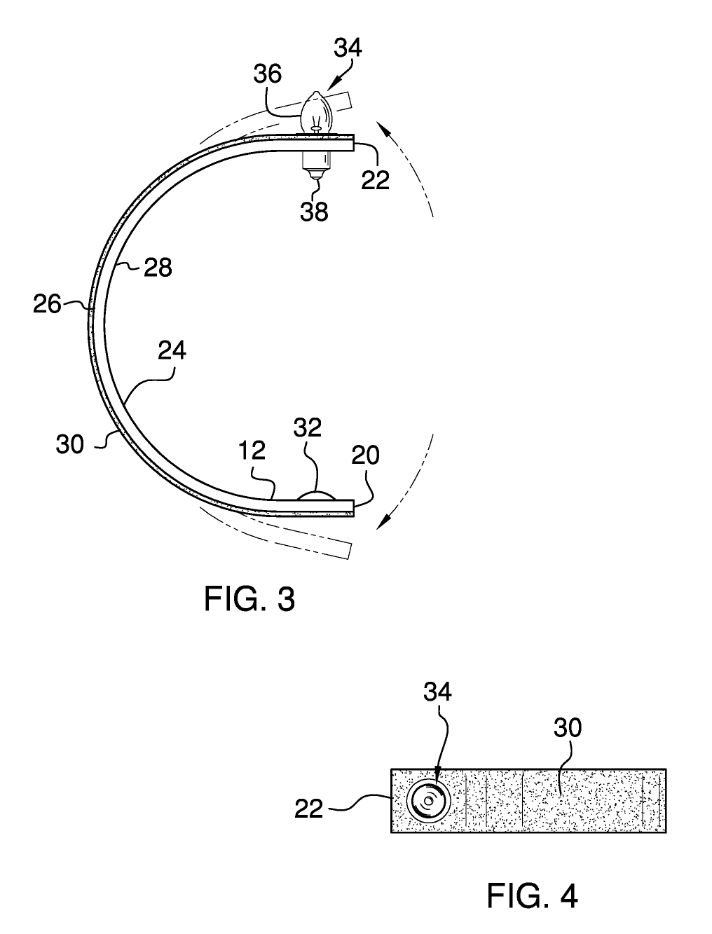

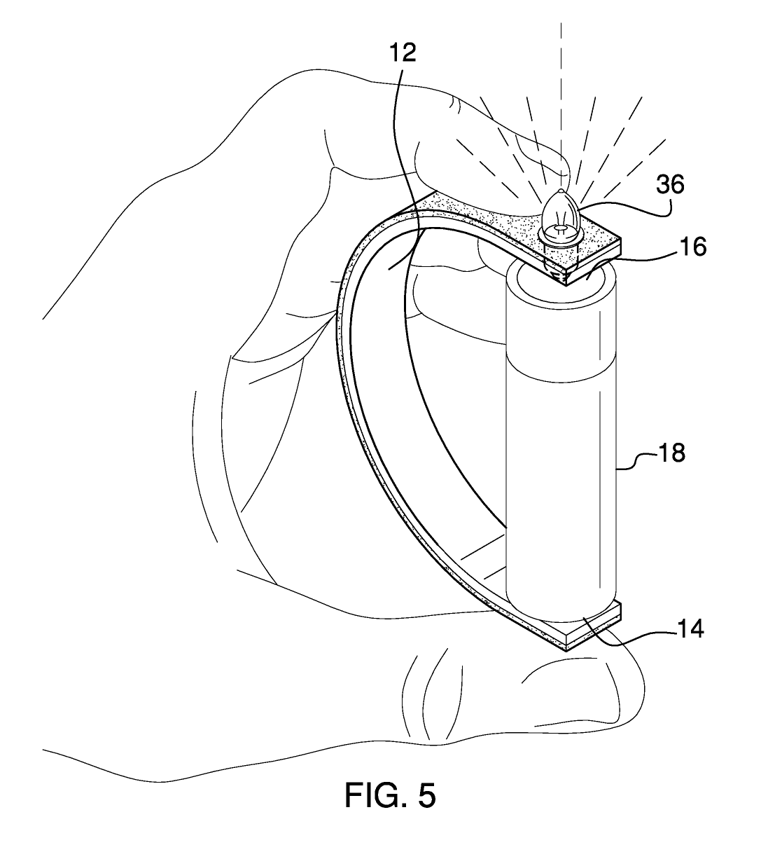

With reference now to the drawings, and in particular to FIGS. 1 through 5 thereof, a new testing device embodying the principles and concepts of an embodiment of the disclosure and generally designated by the reference numeral 10 will be described.

As best illustrated in FIGS. 1 through 5, the battery testing assembly 10 generally comprises a belt 12 that is selectively positioned between a positive terminal 14 and a negative terminal 16 of a battery 18. The battery 18 may be a disposable battery 18 to include, but not be limited to, AA batteries and C cell batteries. The belt 12 is comprised of an electrically conductive material such as steel of the like. Thus, the belt 12 completes a circuit between the positive 14 and negative 16 terminals when the belt 12 is positioned on the positive 14 and negative 16 terminals.

The belt 12 has a first end 20, a second end 22 and an outer surface 24 extending therebetween, and the outer surface 24 has a first side 26 and a second side 28. The belt 12 is arcuate between the first end 20 and the second end 22 such that the first end 20 is spaced from the second end 22. Moreover, the belt 12 is comprised of a resiliently bendable material such that the first end 20 is biased away from the second end 22. The belt 12 may have a length ranging between approximately 10.0 cm and 15.0 cm. Additionally, the first and second end 22s may be spaced apart a distance ranging between approximately 5.0 cm and 8.0 cm.

A shield 30 is provided and the shield 30 is coupled to the belt 12. The shield 30 is positioned on the first side 26 of the belt 12 and the shield 30 is coextensive with the first side 26. Additionally, the shield 30 is comprised of an electrically insulating material such as rubber or the like. A contact 32 is coupled to the belt 12 and the contact 32 is placed in electrical communication with the negative terminal 16 of the battery 18 when the belt 12 is positioned between the negative 16 and positive 14 terminals. The contact 32 is positioned on the second side 28 of the belt 12 and the contact 32 is positioned closer to the first end 20 than the second end 22. Additionally, the contact 32 is in electrical communication with the belt 12.

A light emitter 34 is provided and the light emitter 34 is coupled to the belt 12. The light emitter 34 is placed in electrical communication with the positive terminal 14 of the battery 18 when the belt 12 is positioned between the negative and positive terminal 14s. In this way the light emitter 34 emit lights to check a charge of the battery 18.

The light emitter 34 extends through the first side 26 and the second side 28 and the light emitter 34 is positioned closer to the second end 22 than the first end 20. Additionally, the light emitter 34 includes a bulb 36 and a contact 38. The contact 38 of the light emitter 34 is positioned on the second side 28 of the belt 12 and the bulb 36 is positioned on the shield 30. The light emitter 34 is in electrical communication with the contact 32.

The light emitter 34 may comprise a PR-2 incandescent bulb or the like. Additionally, the light emitter 34 emits an intensity of light that corresponds to a charge of the battery 18. The light emitter 34 emits a minimum intensity of light when the battery 18 has a minimum charge. Moreover, the light emitter 34 emits a maximum intensity of light when the battery 18 has a maximum charge.

In use, the belt 12 is positioned on the battery 18 such that the negative terminal 16 is aligned with the contact 32 and the positive terminal 14 is aligned with the light emitter 34. The belt 12 is compressed to engage the contact 32 and the light emitter 34 to the corresponding positive 14 and negative 16 terminals. Thus, the light emitter 34 emits an intensity of light that corresponds to a charge level of the battery 18. The battery 18 may be one of a plurality of batteries in an electronic device. The belt 12 facilitates the charge level corresponding to each of the batteries in the electronic device to be checked. In this way the battery 18 with the lowest charge can be replaced to continue using the electronic device thereby reducing the cost associated with unnecessarily replacing batteries that have a useful charge.

With respect to the above description then, it is to be realized that the optimum dimensional relationships for the parts of an embodiment enabled by the disclosure, to include variations in size, materials, shape, form, function and manner of operation, assembly and use, are deemed readily apparent and obvious to one skilled in the art, and all equivalent relationships to those illustrated in the drawings and described in the specification are intended to be encompassed by an embodiment of the disclosure.

Therefore, the foregoing is considered as illustrative only of the principles of the disclosure. Further, since numerous modifications and changes will readily occur to those skilled in the art, it is not desired to limit the disclosure to the exact construction and operation shown and described, and accordingly, all suitable modifications and equivalents may be resorted to, falling within the scope of the disclosure. In this patent document, the word “comprising” is used in its non-limiting sense to mean that items following the word are included, but items not specifically mentioned are not excluded. A reference to an element by the indefinite article “a” does not exclude the possibility that more than one of the element is present, unless the context clearly requires that there be only one of the elements.

1. A battery testing assembly being configured to be selectively electrically coupled to a battery to test a charge of the battery, said assembly comprising:
a belt being configured to be positioned between a positive terminal and a negative terminal of a battery, said belt being comprised of an electrically conductive material wherein said belt is configured to complete a circuit between the positive and negative terminals, said belt having a first end, a second end and an outer surface extending therebetween, said outer surface having a first side and a second side, said belt being arcuate such that said first side is convex and said second side is concave;
a contact being coupled to said belt, said contact having an arcuate upper surface extending from said second side of said outer surface of said belt wherein said contact is configured to be placed in electrical communication with the negative terminal of the battery when said belt is positioned between the negative and positive terminals;
a light emitter being coupled to said belt wherein said light emitter is configured to be placed in electrical communication with the positive terminal of the battery when said belt is positioned between the negative and positive terminals, said light emitter being configured to emit light when said belt is positioned between the negative and positive terminals thereby facilitating a charge of the battery to be checked; and
a shield being coupled to said belt, said shield being positioned on said first side of said belt, said shield being coextensive with said first side, said shield being comprised of an electrically insulating material.

2. The assembly according to claim 1, wherein said belt is arcuate between said first end and said second end such that said first end is spaced from the second end, said belt being comprised of a resiliently bendable material such that said first end is biased away from said second end.

3. (canceled)

4. The assembly according to claim 2, wherein said contact is positioned closer to said first end than said second end, said contact being in electrical communication with said belt.

5. The assembly according to claim 1, wherein said light emitter extends through said first side and said second side, said light emitter being positioned closer to said second end than said first end, said light emitter being in electrical communication with said contact.

6. A battery testing assembly being configured to be selectively electrically coupled to a battery to test a charge of the battery, said assembly comprising:
a belt being configured to be positioned between a positive terminal and a negative terminal of a battery, said belt being comprised of an electrically conductive material wherein said belt is configured to complete a circuit between the positive and negative terminals, said belt having a first end, a second end and an outer surface extending therebetween, said outer surface having a first side and a second side, said belt being arcuate such that said first side is convex and said second side is concave, said belt being arcuate between said first end and said second end such that said first end is spaced from the second end, said belt being comprised of a resiliently bendable material such that said first end is biased away from said second end,
a shield being coupled to said belt, said shield being positioned on said first side of said belt, said shield being coextensive with said first side, said shield being comprised of an electrically insulating material;
a contact being coupled to said belt, said contact having an arcuate upper surface extending from said second side of said outer surface of said belt wherein said contact is configured to be placed in electrical communication with the negative terminal of the battery when said belt is positioned between the negative and positive terminals, said contact being positioned on said second side of said belt, said contact being positioned closer to said first end than said second end, said contact being in electrical communication with said belt; and
a light emitter being coupled to said belt wherein said light emitter is configured to be placed in electrical communication with the positive terminal of the battery when said belt is positioned between the negative and positive terminals, said light emitter being configured to emit light when said belt is positioned between the negative and positive terminals thereby facilitating a charge of the battery to be checked, said light emitter extending through said first side and said second side, said light emitter being positioned closer to said second end than said first end, said light emitter being in electrical communication with said contact.
